(19) United States
(12) Patent Application Publication
(10) Pub. No.: US 2025/0346813 A1
(43) Pub. Date: Nov. 13, 2025

(54) PHOTO-ALIGNMENT FILM, OPTICAL FILM, CIRCULARLY POLARIZING PLATE, IMAGE DISPLAY APPARATUS, AND METHOD FOR MANUFACTURING CIRCULARLY POLARIZING PLATE

(71) Applicant: FUJIFILM Corporation, Tokyo (JP)

(72) Inventors: Jun ISHIYAMA, Kanagawa (JP); Taro HASHIZUME, Kanagawa (JP); Akio TAMURA, Kanagawa (JP); Takashi IIZUMI, Kanagawa (JP); Soichiro WATANABE, Kanagawa (JP); Takahiro KATO, Kanagawa (JP)

(73) Assignee: FUJIFILM Corporation, Tokyo (JP)

(21) Appl. No.: 19/278,335

(22) Filed: Jul. 23, 2025

Related U.S. Application Data
(63) Continuation of application No. PCT/JP2024/005935, filed on Feb. 20, 2024.

(30) Foreign Application Priority Data
Feb. 22, 2023 (JP) 2023-025807
Sep. 6, 2023 (JP) 2023-144500

(51) Int. Cl. C09K 19/56; C09K 19/38; G02B 5/30

(52) U.S. Cl. CPC C09K 19/56; C09K 19/3852; G02B 5/3016; C09K 2219/03

(57) ABSTRACT

A photo-alignment film, an optical film, a circularly polarizing plate, an image display apparatus, and a method for manufacturing a circularly polarizing plate, which can improve liquid crystal alignment properties and rub resistance. The photo-alignment film is obtained by curing a composition which contains a photo-alignment polymer having a photo-aligned group and an epoxy compound, in which the photo-alignment film contains a fluorine atom, and a content of the photo-alignment polymer is 1% to 15% by mass with respect to a total solid content of the composition.

### CROSS-REFERENCE TO RELATED APPLICATIONS

This application is a Continuation of PCT International Application No. PCT/JP2024/005935 filed on Feb. 20, 2024, which was published under PCT Article 21(2) in Japanese, and which claims priority under 35 U.S.C. § 119(a) to Japanese Patent Application No. 2023-025807 filed on Feb. 22, 2023 and Japanese Patent Application No. 2023-144500 filed on Sep. 6, 2023. The above applications are hereby expressly incorporated by reference, in their entirety, into the present application.

### BACKGROUND OF THE INVENTION

### 1. Field of the Invention

The present invention relates to a photo-alignment film, an optical film, a circularly polarizing plate, an image display apparatus, and a method for manufacturing a circularly polarizing plate.

### 2. Description of the Related Art

Optical films such as optical compensation sheets and retardation films are used in various image display apparatus from the viewpoint of solving image coloration or widening a viewing angle.

A stretched birefringence film has been used as an optical film, but in recent years, it has been proposed to use a liquid crystal cured layer formed of a liquid crystal compound in place of the stretched birefringence film.

In the formation of such a liquid crystal cured layer, a photo-alignment film obtained by performing a photo-alignment treatment may be used in order to align the liquid crystal compound.

For example, WO2010/150748A discloses a liquid crystal alignment layer (photo-alignment film) formed of a thermosetting film-forming composition which contains an acrylic copolymer (photo-alignment polymer) having a photodimerization site such as a cinnamoyl group and a crosslinking agent ([Claim 1], [Claim 3], [Claim 11], and [0028]).

### SUMMARY OF THE INVENTION

As a result of studying the photo-alignment film disclosed in WO2010/150748A, the present inventors have found that, depending on the content of the photo-alignment polymer and the type of crosslinking agent, alignment properties of the liquid crystal cured layer (hereinafter, also referred to as “liquid crystal alignment properties”) formed on the upper layer of the photo-alignment film may be deteriorated, and the liquid crystal alignment properties in a portion receiving a frictional force (for example, a load locally applied by fine scratches on the roll surface or attached dust on the roll surface) may be deteriorated. Hereinafter, the liquid crystal alignment properties in the portion receiving the frictional force are referred to as “rub resistance”.

Therefore, an object of the present invention is to provide a photo-alignment film, an optical film, a circularly polarizing plate, an image display apparatus, and a method for manufacturing a circularly polarizing plate, which can improve the liquid crystal alignment properties and the rub resistance.

As a result of intensive studies to achieve the above-described object, the present inventors have found that, in a case where a photo-alignment film, which is obtained by curing a composition containing a photo-alignment polymer and an epoxy compound, contains a fluorine atom or a silicon atom, and has a content of the photo-alignment polymer of 1% to 15% by mass with respect to the total solid content of the composition is used, both the liquid crystal alignment properties and the rub resistance are improved, thereby completing the present invention.

That is, the present inventors have found that the above-described object can be achieved by adopting the following configurations.
[1] A photo-alignment film obtained by curing a composition which contains a photo-alignment polymer having a photo-aligned group and an epoxy compound,
in which the photo-alignment film contains a fluorine atom or a silicon atom, and
a content of the photo-alignment polymer is 1% to 15% by mass with respect to a total solid content of the composition.
[2] The photo-alignment film according to [1],
in which an element ratio of fluorine on one surface of the photo-alignment film is 0.5 to 3.0 atomic %.
[3] The photo-alignment film according to [1],
in which an element ratio of silicon on one surface of the photo-alignment film is 0.2 to 1.25 atomic %.
[4] The photo-alignment film according to any one of [1] to [3],
in which the photo-alignment polymer contains a fluorine atom.
[5] The photo-alignment film according to any one of [1] to [4],
in which the photo-alignment polymer contains a silicon atom.
[6] The photo-alignment film according to any one of [1] to [5],
in which the photo-alignment polymer has a repeating unit represented by Formula (A) described later.
[7] The photo-alignment film according to any one of [1] to [6],
in which the photo-alignment film contains no liquid crystal compound.
[8] An optical film comprising:
the photo-alignment film according to any one of [1] to [7]; and
a liquid crystal cured layer.
[9] The optical film according to [8],
in which an angle between a slow axis of the liquid crystal cured layer and a longitudinal direction of the optical film is 50° to 90°.
[10] The optical film according to [8] or [9],
in which the liquid crystal cured layer is a layer obtained by fixing an alignment state of a liquid crystal composition containing a disk-like liquid crystal compound.
[11] A circularly polarizing plate comprising:
the optical film according to [8] or [9]; and
a polarizer.
[12] An image display apparatus comprising:
the photo-alignment film according to any one of [1] to [7].
[13] A method for manufacturing a circularly polarizing plate, comprising, in the following order:
a step 1 of producing an optical film by applying a liquid crystal composition containing a liquid crystal compound on the photo-alignment film according to any one of [1] to [7] and curing the liquid crystal composition to form a liquid crystal cured layer;
a step 2 of bonding the optical film to a polarizer; and
a step 3 of peeling off the photo-alignment film from the optical film.

According to the present invention, it is possible to provide a photo-alignment film, an optical film, a circularly polarizing plate, an image display apparatus, and a method for manufacturing a circularly polarizing plate, which can improve liquid crystal alignment properties and rub resistance.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Any numerical range expressed using “to” in the present specification refers to a range including the numerical values before and after the “to” as a lower limit value and an upper limit value, respectively.

In addition, in a range of numerical values described in stages in the present specification, the upper limit value or the lower limit value described in a certain range of numerical values may be replaced with an upper limit value or a lower limit value of the range of numerical values described in other stages. In addition, regarding the numerical range described in the present specification, an upper limit value or a lower limit value described in a numerical value may be replaced with a value described in Examples.

In addition, in the present specification, substances corresponding to respective components may be used alone or in combination of two or more kinds thereof. Here, in a case where two or more types of substances are used in combination for each component, the content of the component refers to a total content of the substances used in combination unless otherwise specified.

In addition, the bonding direction of a divalent group (for example, —O—CO—) described in this specification is not particularly limited, and for example, in a case where L² in a “L¹-L²-L³” bond is —O—CO—, and a bonding position on the L¹ side is represented by *1 and a bonding position on the L³ side is represented by *2, L² may be *1-O—CO—*2 or *1-CO—O—*2.

### [Photo-Alignment Film]

The photo-alignment film according to the embodiment of the present invention is a photo-alignment film obtained by curing a composition (hereinafter, also referred to as “composition for forming a photo-alignment film”) containing a photo-alignment polymer having a photo-aligned group and an epoxy compound.

In addition, the photo-alignment film according to the embodiment of the present invention contains a fluorine atom or a silicon atom.

In addition, a content of the photo-alignment polymer in the photo-alignment film according to the embodiment of the present invention is 1% to 15% by mass with respect to the total solid content of the composition for forming a photo-alignment film.

Here, the fact that the photo-alignment film according to the embodiment of the present invention contains a fluorine atom or a silicon atom can be confirmed by, for example, X-ray photoelectron spectroscopy (XPS).

In the present invention, as described above, in a case where a photo-alignment film, which is obtained by curing a composition containing a photo-alignment polymer and an epoxy compound, contains a fluorine atom or a silicon atom, and has a content of the photo-alignment polymer of 1% to 15% by mass with respect to the total solid content of the composition is used, both the liquid crystal alignment properties and the rub resistance are improved.

The reason for this is not clear, but the present inventors presume as follows.

That is, it is considered that, since the photo-alignment film is obtained by curing the composition containing the specific amount of the photo-alignment polymer and the epoxy compound, and contains a fluorine atom or a silicon atom, a strength of the photo-alignment film is improved while maintaining an alignment restriction force due to the photo-alignment polymer, and thus both the liquid crystal alignment properties and the rub resistance are improved. In particular, in a case where the photo-alignment film receives a frictional force (for example, a load locally applied by fine scratches on the roll surface or attached dust on the roll surface), it is considered that molecular alignment of a portion receiving the frictional force (for example, stretching in a transport direction in a case of contact with a transport roll) is suppressed, generation of the alignment restriction force locally generated in the portion receiving the frictional force can be suppressed, and thus the liquid crystal alignment properties of the portion receiving the frictional force are also improved.

Hereinafter, the photo-alignment polymer and the epoxy compound, contained in the composition for forming a photo-alignment film, will be described in detail.

### [Photo-Alignment Polymer]

The photo-alignment polymer contained in the composition for forming a photo-alignment film is not particularly limited as long as it is a polymer having a photo-aligned group.

Here, the photo-aligned group refers to a group having a photo-alignment function in which rearrangement or an anisotropic chemical reaction is induced by irradiation with light having anisotropy (for example, plane-polarized light), and from the viewpoint of excellent alignment uniformity and improved thermal stability and chemical stability, a photo-aligned group in which at least one of dimerization or isomerization is caused by an action of light is preferable.

Suitable examples of the photo-aligned group which is dimerized by the action of light include groups having a skeleton of at least one derivative selected from the group consisting of a cinnamic acid derivative, a coumarin derivative, a chalcone derivative, a maleimide derivative, and a benzophenone derivative.

On the other hand, suitable examples of the photo-aligned group which is isomerized by the action of light include groups having a skeleton of at least one compound selected from the group consisting of an azobenzene compound, a stilbene compound, a spiropyran compound, a cinnamic acid compound, and a hydrazono-β-ketoester compound.

As the photo-aligned group, a group having a skeleton of at least one derivative selected from the group consisting of cinnamic acid derivatives, coumarin derivatives, chalcone derivatives, and maleimide derivatives, or a group having a skeleton of at least one compound selected from the group consisting of azobenzene compounds, stilbene compounds, and spiropyran compounds is preferable, and a group having a skeleton of a cinnamic acid derivative or a coumarin derivative is more preferable.

In the present invention, the photo-alignment polymer is preferably a polymer having a repeating unit including a photo-aligned group (hereinafter, also referred to as “repeating unit A”); and from the reason that the rub resistance is further improved, it is more preferable that the photo-alignment polymer is a polymer having a repeating unit represented by Formula (A). In a case where the photo-alignment film has a repeating unit represented by Formula (A), it is considered that, even in a case where the portion of the photo-alignment film, receiving the frictional force, is molecularly aligned, hydrogen-bonding property between a main chain moiety of the photo-alignment polymer and the liquid crystal compound in the upper layer (liquid crystal cured layer) is lowered, and thus the rub resistance is further improved.

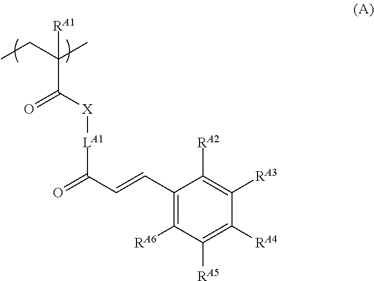

In Formula (A), R^{A1} represents a hydrogen atom or a substituent.

In addition, L^{A1} represents a single bond or a divalent linking group.

In addition, R^{A2}, R^{A3}, R^{A4}, R^{A5}, and R^{A6} each independently represent a hydrogen atom or a substituent. Two adjacent groups of R^{A2}, R^{A3}, R^{A4}, R^{A5}, and R^{A6} may be bonded to each other to form a ring.

In Formula (A), R^{A1} represents a hydrogen atom or a substituent.

Here, the type of the substituent represented as one aspect of R^{A1} is not particularly limited, and examples thereof include known substituents.

Examples of the substituent include a halogen atom, an alkyl group, an alkoxy group, an aryl group, an aryloxy group, a cyano group, a carboxy group, an alkoxycarbonyl group, and a hydroxyl group.

Examples of the halogen atom include a fluorine atom, a chlorine atom, a bromine atom, and an iodine atom, and a fluorine atom or a chlorine atom is preferable.

As the alkyl group, for example, a linear alkyl group having 1 to 18 carbon atoms or a branched or cyclic alkyl group having 3 to 18 carbon atoms is preferable, a linear alkyl group having 1 to 4 carbon atoms is more preferable, and a methyl group or an ethyl group is still more preferable.

As the alkoxy group, for example, an alkoxy group having 1 to 18 carbon atoms is preferable, an alkoxy group having 1 to 4 carbon atoms is more preferable, and a methoxy group or an ethoxy group is still more preferable.

Examples of the aryl group include an aryl group having 6 to 12 carbon atoms, and examples thereof include a phenyl group, an α-methylphenyl group, and a naphthyl group. Among these, a phenyl group is preferable.

Examples of the aryloxy group include a phenoxy group, a naphthoxy group, an imidazoyloxy group, a benzimidazoyloxy group, a pyridine-4-yloxy group, a pyrimidinyloxy group, a quinazolinyloxy group, a purinyloxy group, and a thiophen-3-yloxy group.

Examples of the alkoxycarbonyl group include a methoxycarbonyl group and an ethoxycarbonyl group.

R^{A1} is preferably a hydrogen atom or an alkyl group, and more preferably a hydrogen atom or a methyl group.

In Formula (A), L^{A1} represents a single bond or a divalent linking group.

Here, examples of the divalent linking group represented as one aspect of L^{A1} include a divalent hydrocarbon group which may have a substituent, a divalent heterocyclic group which may have a substituent, —O—, —S—, —N(Q)-, —CO—, and a group obtained by combining these groups. Q represents a hydrogen atom or a substituent.

Examples of the divalent hydrocarbon group include divalent aliphatic hydrocarbon groups such as an alkylene group having 1 to 10 carbon atoms, an alkenylene group having 1 to 10 carbon atoms, and an alkynylene group having 1 to 10 carbon atoms; and divalent aromatic hydrocarbon groups such as an arylene group.

Examples of the divalent heterocyclic group include divalent aromatic heterocyclic groups. Specific examples thereof include a pyridylene group (pyridine-diyl group), a pyridazine-diyl group, an imidazole-diyl group, thienylene (thiophene-diyl group), and a quinolylene group (quinoline-diyl group).

In addition, examples of the group formed by combining the above-described groups include a group obtained by combining at least two selected from the group consisting of a divalent hydrocarbon group, a divalent heterocyclic group, —O—, —S—, —N(Q)-, and —CO—. Examples thereof include-divalent hydrocarbon group-O— and -divalent hydrocarbon group-N(Q)-.

L^{A1} is preferably a divalent linking group obtained by combining at least two selected from the group consisting of a linear alkylene group having 1 to 10 carbon atoms, which may have a substituent, a branched alkylene group having 3 to 10 carbon atoms, which may have a substituent, a cyclic alkylene group having 3 to 10 carbon atoms, which may have a substituent, an arylene group having 6 to 12 carbon atoms, which may have a substituent, —O—, and —N(Q)-; and more preferably a divalent linking group obtained by combining at least two selected from the group consisting of a linear alkylene group having 1 to 10 carbon atoms, which may have a substituent, a cyclic alkylene group having 3 to 10 carbon atoms, which may have a substituent, —O—, and —NH—.

Examples of the substituent which may be included in the divalent hydrocarbon group (including an alkylene group and the like) and the divalent heterocyclic group described above and the substituent represented as one aspect of Q include the groups exemplified in the above-described substituent represented as one aspect of R^{A1}.

In Formula (A), R^{A2}, R^{A3}, R^{A4}, R^{A5}, and R^{A6} each independently represent a hydrogen atom or a substituent. Two adjacent groups of R^{A2}, R^{A3}, R^{A4}, R^{A5}, and R^{A6} may be bonded to each other to form a ring.

Here, examples of the substituent represented as one aspect of R^{A2}, R^{A3}, R^{A4}, R^{A5}, and R^{A6} include the groups exemplified in the above-described substituent represented as one aspect of R^{A1}.

In addition, from the reason that the liquid crystal alignment properties are further improved, the substituent represented by one aspect of R^{A2}, R^{A3}, R^{A4}, R^{A5}, and R^{A6} is each independently preferably a halogen atom, a linear alkyl group having 1 to 20 carbon atoms (preferably having 1 to 6 carbon atoms), a branched or cyclic alkyl group having 3 to 20 carbon atoms (preferably having 3 to 6 carbon atoms), a linear halogenated alkyl group having 1 to 20 carbon atoms (preferably having 1 to 12 carbon atoms), an alkoxy group having 1 to 20 carbon atoms (preferably having 3 to 18 carbon atoms), an aryl group having 6 to 20 carbon atoms (preferably having 6 to 12 carbon atoms), an aryloxy group having 6 to 20 carbon atoms (preferably having 6 to 12 carbon atoms), a hydroxy group, a cyano group, an amino group, or a group represented by Formula (4). The above-described substituent may include a linking group represented by —(CH₂)ₙₐ— or —O—(CH₂)ₙₐ—. na represents an integer of 1 to 10.

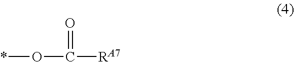

Here, in Formula (4), * represents a bonding position.

R^{A7} represents an alkyl group having 1 to 20 carbon atoms.

Examples of the halogen atom include a fluorine atom, a chlorine atom, a bromine atom, and an iodine atom, and a fluorine atom or a chlorine atom is preferable.

From the reason that the photo-aligned group easily interacts with the liquid crystal compound and the liquid crystal alignment properties are further improved, it is preferable that, among R^{A2}, R^{A3}, R^{A4}, R^{A5}, and R^{A6} in Formula (A), at least R^{A4} represents the above-described substituent (preferably, the alkoxy group or halogenated alkyl group having 1 to 20 carbon atoms); and from the reason that linearity of the obtained photo-alignment polymer is improved, the photo-aligned group easily interacts with the liquid crystal compound, and the liquid crystal alignment properties are further improved, it is more preferable that all of R^{A2}, R^{A3}, R^{A5}, and R^{A6} represent a hydrogen atom.

Specific examples of the repeating unit A include repeating units represented by Formulae A-1 to A-31. The repeating units represented by Formulae A-30 and A-31 correspond to a repeating unit including a fluorine atom together with a photo-aligned group.

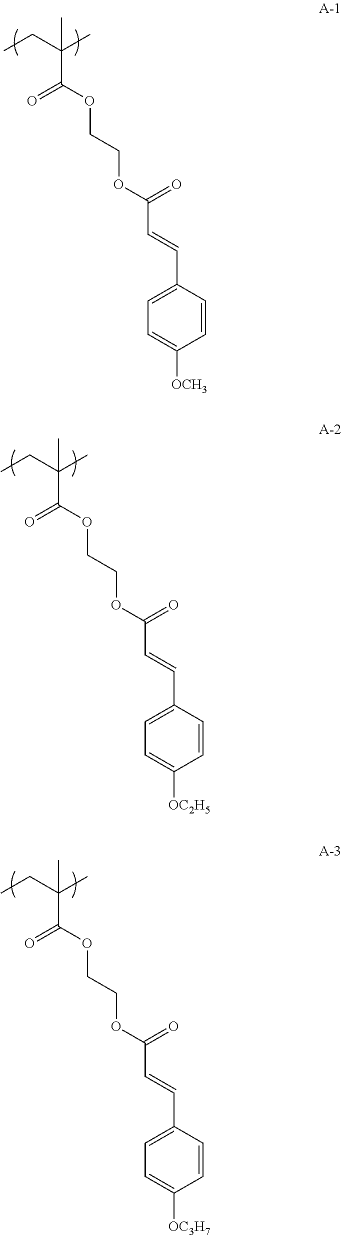

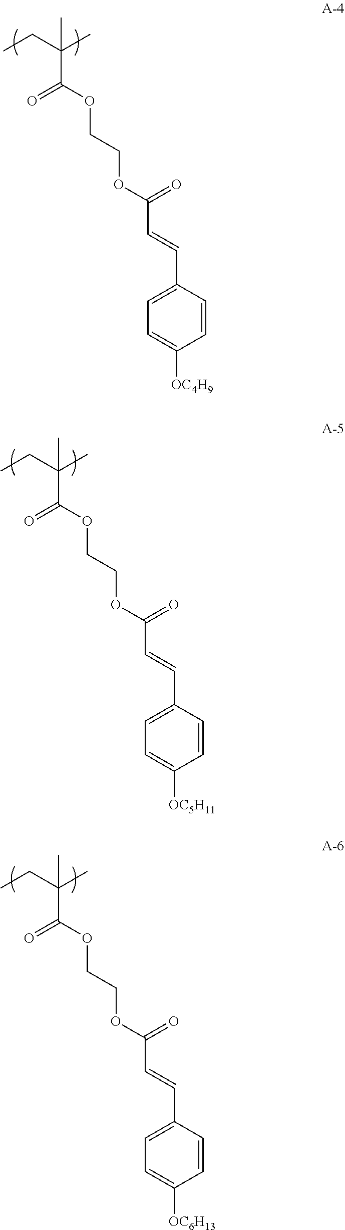

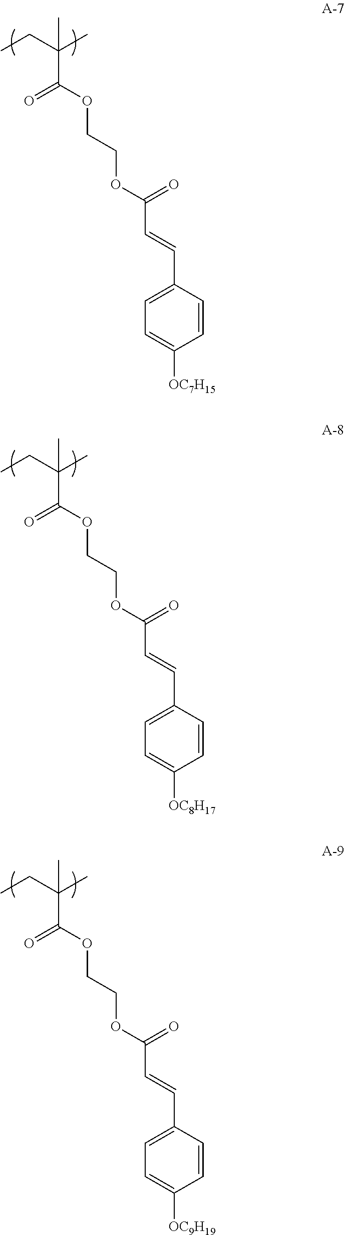

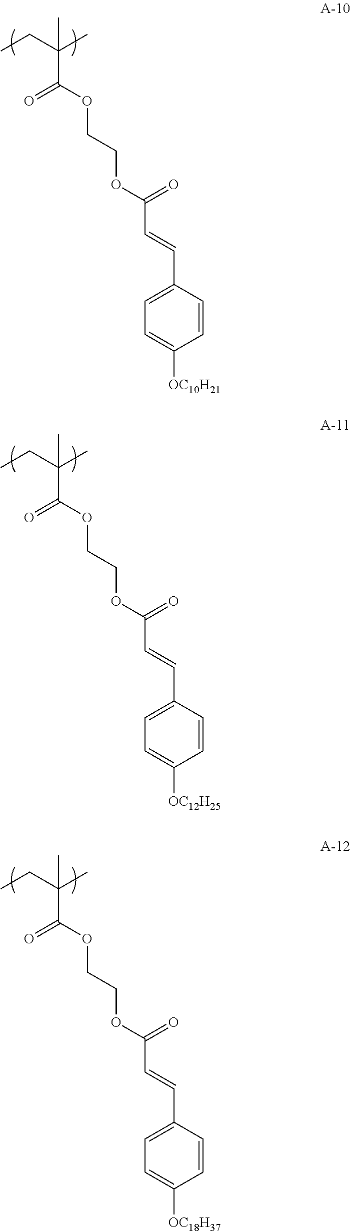

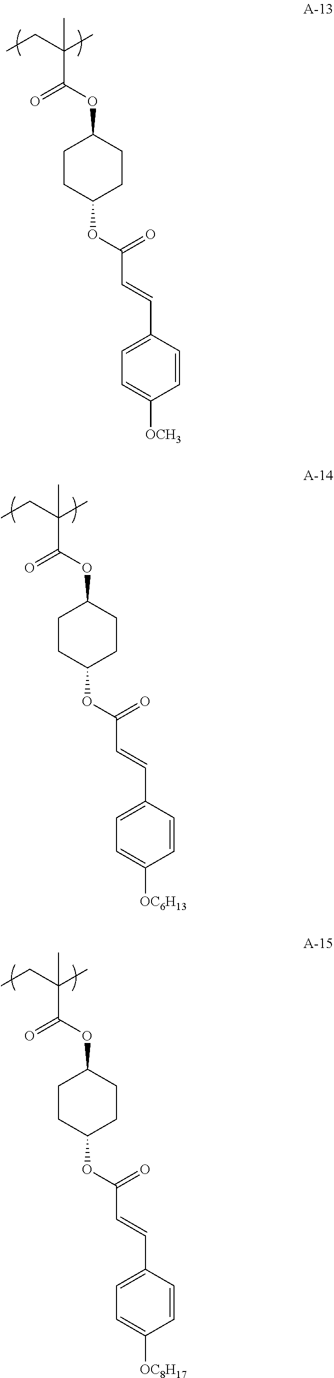

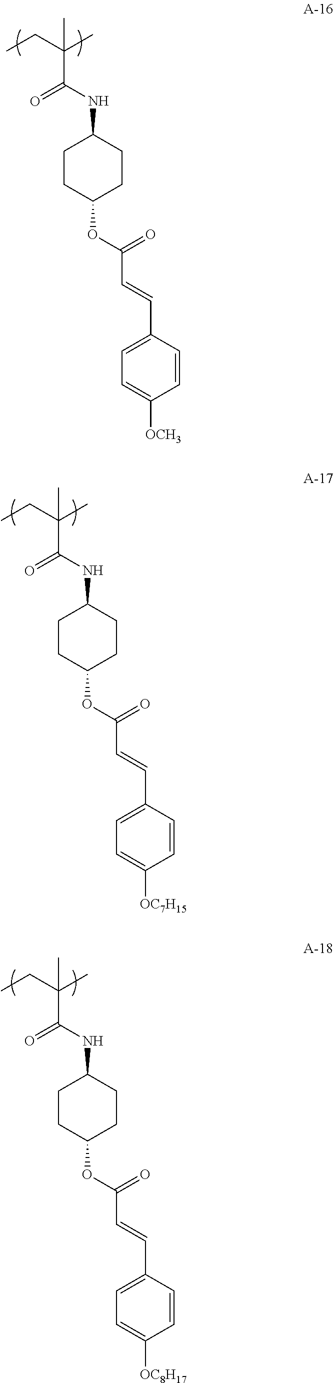

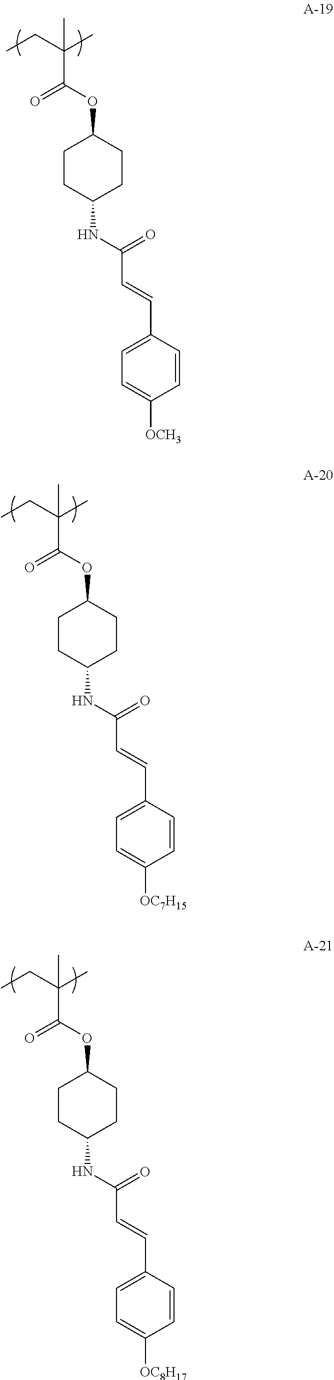

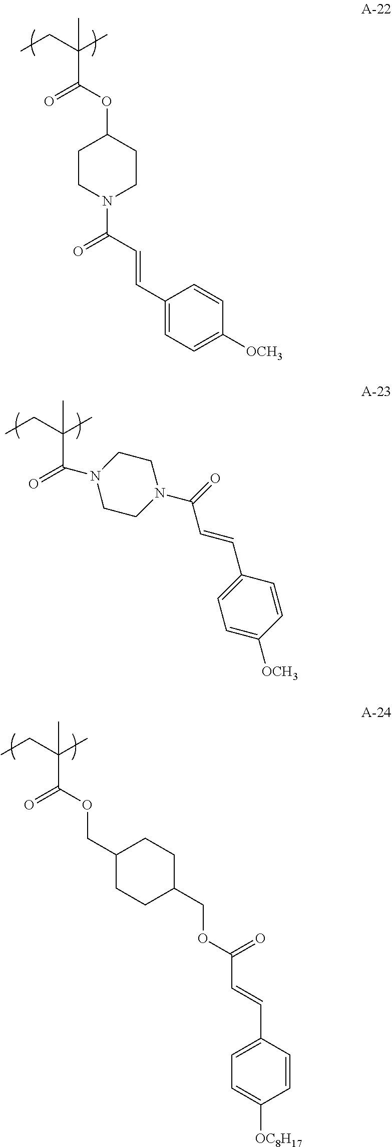

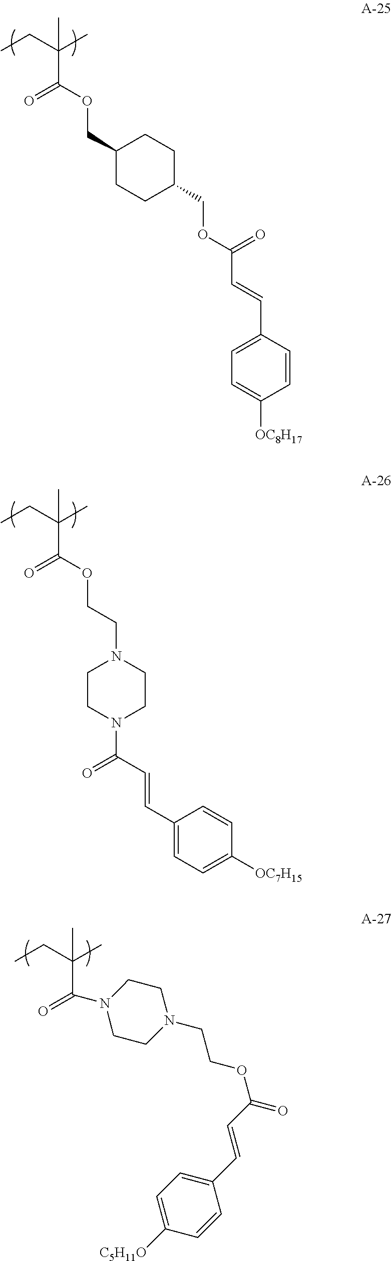

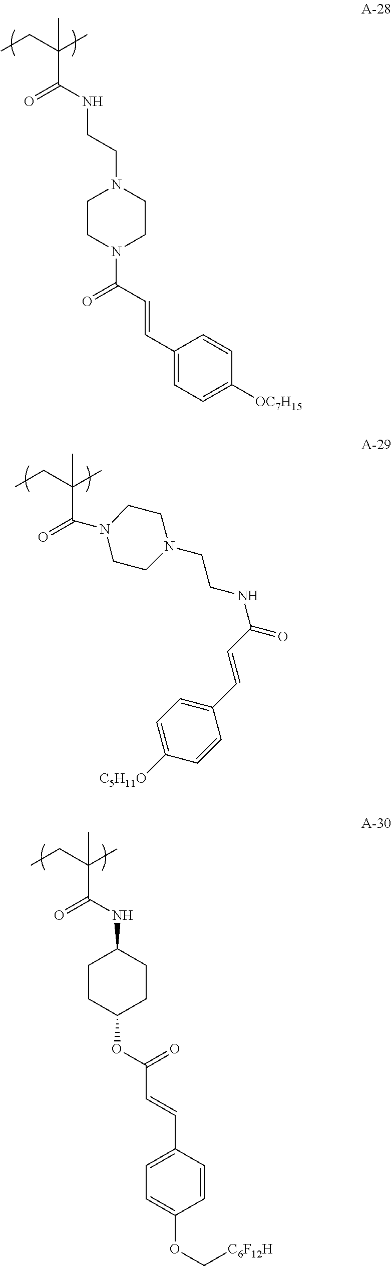

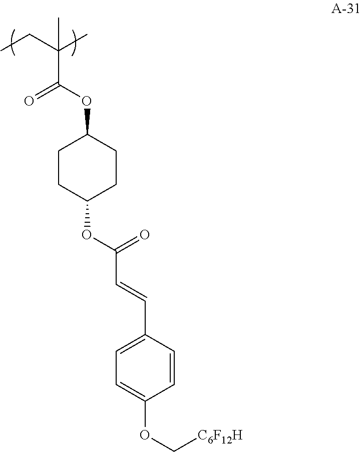

Other specific examples of the repeating unit A also include a repeating unit including, together with a photo-aligned group, a group which is eliminated during the production of the photo-alignment film (after the coating step), for example, a cleavage group described in WO2018/216812A.

For the reason that the liquid crystal alignment properties are further improved, a content of the repeating unit A is preferably 5% to 50% by mass, and more preferably 10% to 40% by mass with respect to all repeating units of the photo-alignment polymer.

In the present invention, from the reason that the liquid crystal alignment properties are further improved, it is preferable that the photo-alignment polymer contains a fluorine atom, it is more preferable that the photo-alignment polymer has a partial structure represented by Formula (1), and it is still more preferable that the photo-alignment polymer has a group represented by Formula (2).

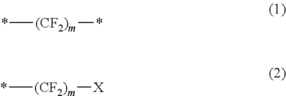

In Formulae (1) and (2), * represents a bonding position.

In addition, in Formulae (1) and (2), m represents an integer of 2 to 20, preferably an integer of 3 to 12 and more preferably an integer of 4 to 8.

In addition, in Formula (2), X represents a hydrogen atom or a fluorine atom, and a hydrogen atom is preferable.

In the present invention, an aspect in which the partial structure represented by Formula (1) or the group represented by Formula (2) is included in the above-described repeating unit A may be adopted, or an aspect in which the partial structure represented by Formula (1) or the group represented by Formula (2) is included in a repeating unit different from the above-described repeating unit A may be adopted.

Here, specific examples of the former aspect include an aspect in which a linear halogenated alkyl group having 2 to 20 carbon atoms is included as the substituent represented by one aspect of R^{A2}, R^{A3}, R^{A4}, R^{A5}, and R^{A6} in Formula (A); and more specific examples thereof include an aspect in which R^{A2}, R^{A3}, R^{A5}, or R^{A6} in Formula (A) represents a hydrogen atom, and R^{A4} in Formula (A) represents a linear halogenated alkyl group having 2 to 20 carbon atoms. Examples of the linear halogenated alkyl group having 2 to 20 carbon atoms include examples of the linear halogenated alkyl group having 1 to 20 carbon atoms described above, excluding a trifluoromethyl group.

On the other hand, specific examples of the latter aspect include an aspect of a copolymer having the above-described repeating unit A and a repeating unit represented by Formula (B) (hereinafter, also referred to as “repeating unit B”).

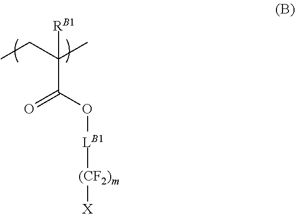

In Formula (B), R^{B1} represents a hydrogen atom or a substituent.

In addition, in Formula (B), L^{B1} represents a single bond or a divalent linking group.

In addition, in Formula (B), X represents a hydrogen atom or a fluorine atom, and m represents an integer of 2 to 20.

In Formula (B), R^{B1} represents a hydrogen atom or a substituent.

The type of the substituent represented as one aspect of R^{B1} is not particularly limited, examples thereof include known substituents, specifically groups exemplified for the substituent represented as one aspect of R^{A1} in Formula (A) described above. Among these, an alkyl group having 1 to 12 carbon atoms is preferable, a linear alkyl group having 1 to 8 carbon atoms or a branched alkyl group having 3 to 8 carbon atoms is more preferable, and a methyl group is still more preferable.

In addition, the substituent represented by one aspect of R^{B1} may be a group represented by -L^{B1}_(CF₂)ₘ—X. The definitions of L^{B1}, m, and X are the same as the definitions described in Formula (B).

In addition, R^{B1} preferably represents a hydrogen atom or a methyl group.

In Formula (B), L^{B1} represents a single bond or a divalent linking group.

Examples of the divalent linking group represented as one aspect of L^{B1} include the same group as those exemplified for the divalent linking group represented as one aspect of L^{A1} in Formula (A) described above. As L^{B1}, a linear alkylene group having 1 to 10 carbon atoms is preferable.

In Formula (B), X represents a hydrogen atom or a fluorine atom, and a hydrogen atom is preferable.

In Formula (B), m represents an integer of 2 to 20, preferably an integer of 3 to 12 and more preferably an integer of 4 to 8.

Specific examples of the repeating unit B include repeating units represented by Formulae B-1 to B-7.

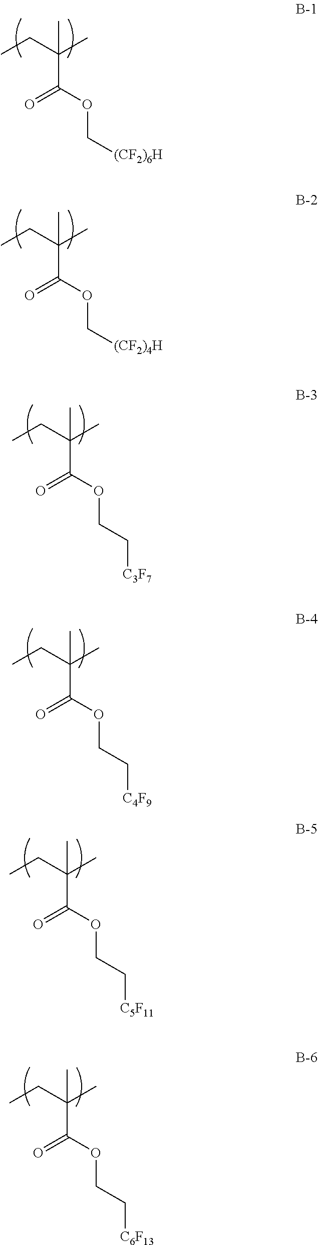

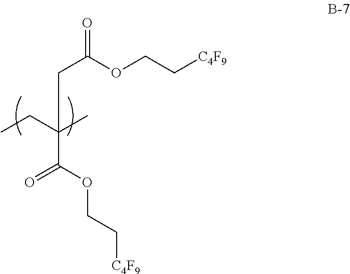

A content of the repeating unit B is not particularly limited, but for the reason that the liquid crystal alignment properties are further improved, it is preferably 1% to 15% by mass, and more preferably 2% to 10% by mass with respect to all repeating units of the photo-alignment polymer.

In the present invention, from the reason that the liquid crystal alignment properties are further improved, it is preferable that the photo-alignment polymer contains a silicon atom, and it is more preferable that the photo-alignment polymer has a repeating unit represented by Formula (3).

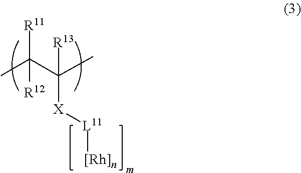

In Formula (3), R¹¹ and R¹² each independently represent a hydrogen atom or an alkyl group.

R¹³ represents a hydrogen atom or a substituent.

X represents an (m+1)-valent linking group.

L¹¹ represents a single bond or an (n+1)-valent linking group. n represents an integer of 1 to 4. m represents an integer of 1 to 5.

Rh represents a substituent having two or more groups represented by Formula (S) (hereinafter, also referred to as “substituent SI”).

Examples of the alkyl group represented by one aspect of R¹¹ and R¹² include a linear alkyl group having 1 to 18 carbon atoms, a branched alkyl group having 3 to 18 carbon atoms, and a cyclic alkyl group; and specific examples thereof include a methyl group, an ethyl group, a propyl group, an isopropyl group, a butyl group (for example, an n-butyl group, a sec-butyl group, an iso-butyl group, and a tert-butyl group), and a cyclohexyl group.

R¹¹ and R¹² are preferably a hydrogen atom.

Examples of the substituent represented by one aspect of R¹³ include a hydroxy group, an alkyl group, an alkenyl group, and an aryl group.

In addition, examples of the substituent represented by one aspect of R¹³ also include a -L^{R}-hydroxy group, a -L^{R}-alkyl group, a -L^{R}-alkenyl group, and a -L^{R}-aryl group. L^{R} represents a divalent linking group. Examples of the divalent linking group represented by L^{R} include —O—, —S—, —CO—, —NR^{N}—, —CH═CH—, —C≡C—, a divalent cyclic group, an alkylene group, and a divalent group obtained by combining these groups; and a —CH₂—COO-alkylene group-hydroxy group is preferable. R^{N} represents a hydrogen atom or an alkyl group having 1 to 12 carbon atoms.

As the alkyl group represented by one aspect of R¹³, a linear alkyl group having 1 to 4 carbon atoms is preferable, and a methyl group or an ethyl group is more preferable.

It is preferable that R¹³ represents a hydrogen atom or a methyl group.

The (m+1)-valent linking group represented by X is not particularly limited, and examples thereof include a divalent (that is, m=1) linking group such as —CO—, —O—, —COO—, and —CONH—, and a trivalent to hexavalent (that is, m=integer of 2 to 5) linking group such as a residue obtained by removing (m+1) hydrogen atoms bonded to a carbon atom or a nitrogen atom constituting a ring of an aromatic ring (for example, a benzene-1,2,3-triyl group).

Here, from the reason that the liquid crystal alignment properties are further improved, the (n+1)-valent linking group represented by one aspect of L¹¹ is an (m+1)-valent hydrocarbon group having 1 to 24 carbon atoms, which may have a substituent, and is preferably a hydrocarbon group in which a part of carbon atoms constituting the hydrocarbon group may be substituted with a heteroatom, and more preferably an aliphatic hydrocarbon group which may contain an oxygen atom or a nitrogen atom and has 1 to 10 carbon atoms.

In addition, the (n+1)-valent linking group is preferably a divalent linking group.

Examples of the divalent linking group include a hydrocarbon group having 1 to 20 carbon atoms; and an alkylene group having 1 to 20 carbon atoms is preferable, and a linear alkylene group having 1 to 18 carbon atoms, a branched alkylene group having 3 to 18 carbon atoms, or a cyclic alkylene group having 3 to 20 carbon atoms is more preferable.

L¹¹ is preferably a single bond or a linear alkylene group having 1 to 18 carbon atoms, and more preferably a single bond, a methylene group, an ethylene group, or a propylene group.

The substituent SI represented by Rh is not particularly limited as long as it is the substituent having two or more groups represented by Formula (S).

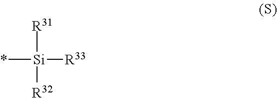

In Formula (S), * represents a bonding position.

R³¹, R³², and R³³ each independently represent an alkyl group, an alkenyl group, an aryl group, or an alkylene aryl group.

Here, in the substituent represented by Rh, a plurality of R³¹'s may be the same or different from each other, a plurality of R³²'s may be the same or different from each other, and a plurality of R³³'s may be the same or different from each other.

Examples of the alkyl group represented by one aspect of R³¹, R³², and R³³ include a linear alkyl group having 1 to 18 carbon atoms, a branched alkyl group having 3 to 18 carbon atoms, and a cyclic alkyl group.

Examples of the alkenyl group represented by one aspect of R³¹, R³², and R³³ include an alkenyl group having 2 to 12 carbon atoms.

Examples of the aryl group represented by one aspect of R³¹, R³², and R³³ include an aryl group having 6 to 12 carbon atoms. Specific examples thereof include a phenyl group, an α-methylphenyl group, and a naphthyl group.

Examples of the alkylene aryl group represented by one aspect of R³¹, R³², and R³³ include an alkylene aryl group having 7 to 30 carbon atoms.

As R³¹, R³², and R³³ in Formula (S), an alkyl group is preferable, and a linear alkyl group having 1 to 18 carbon atoms is more preferable.

The number of groups represented by Formula (S) in the substituent SI is 2 or more, and from the reason that a surface tension of the liquid crystal composition is reduced and unevenness can be suppressed during the formation of the liquid crystal cured layer, it is preferably 3 to 8, more preferably 3 to 6, and still more preferably 3 to 5.

As the substituent SI, a group represented by Formula (S1) is preferable.

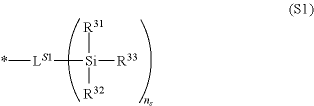

In Formula (S1), * represents a bonding position.

R³¹, R³², and R³³ each independently represent an alkyl group, an alkenyl group, an aryl group, or an alkylene aryl group. Here, a plurality of R³¹'s may be the same or different from each other, a plurality of R³²'s may be the same or different from each other, and a plurality of R³³'s may be the same or different from each other.

L^{S1} represents an (n_{S}+1)-valent linking group.

n_{S} represents an integer of 3 or more.

R³¹, R³², and R³³ in Formula (S1) each have the same meaning as R³¹, R³², and R³³ in Formula (S), and suitable aspects thereof are also the same.

The (n_{S}+1)-valent linking group represented by L^{S1} is, for example, preferably an (n_{S}+1)-valent hydrocarbon group having 1 to 15 carbon atoms, which may have a substituent, in which a part of carbon atoms constituting the hydrocarbon group may be substituted with a heteroatom. For example, in a case where the above-described (n_{S}+1)-valent linking group is a tetravalent hydrocarbon group, one or two or more non-adjacent-CH₂—'s of —CH₂—'s constituting a part of the tetravalent hydrocarbon group may be each independently substituted with —O—, —CO—, —S—, —NH—, or —N(Q_{S})-. Q_{S} represents a substituent; and the substituent represented by Q_{S} is preferably an alkyl group, more preferably a linear alkyl group having 1 to 4 carbon atoms, and still more preferably a methyl group or an ethyl group.

As the substituent which can be included int the hydrocarbon group, an alkyl group is preferable, a linear alkyl group having 1 to 4 carbon atoms is more preferable, and a methyl group or an ethyl group is still more preferable.

In addition, examples of the heteroatom include a silicon atom, an oxygen atom, and a nitrogen atom, and a silicon atom or an oxygen atom is preferable.

As L^{S1}, an (n_{S}+1)-valent linking group having a heteroatom is also preferable.

Examples of the (n_{S}+1)-valent linking group represented by one aspect of L^{S1} include a tetra- or higher valent linking group consisting of a combination of a group selected from an ether group and a thioether group, an alkylene group, and a quaternary carbon atom bonded to the alkylene group.

The above-described (n_{S}+1)-valent linking group is preferably a tetravalent linking group consisting of a combination of an alkylene group having 1 to 6 carbon atoms, a quaternary carbon atom bonded to the alkylene group, and three ether groups bonded to the quaternary carbon atom.

The above-described alkylene group may be linear, branched, or cyclic, and is preferably linear.

As the (n_{S}+1)-valent linking group, a group represented by Formula (LS-1) or a group represented by Formula (LS-2) is preferable, and a group represented by Formula (LS-1) is more preferable.

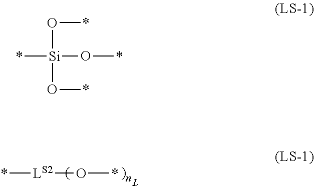

In Formula (LS-1), * represents a bonding position.

In addition, in Formula (LS-2), * represents a bonding position.

L^{S2} represents an (n_{L}+1)-valent hydrocarbon group in which a part of carbon atoms may be substituted with a heteroatom.

n_{L} represents an integer of 3 or more.

The (n_{L}+1)-valent hydrocarbon group represented by L^{S2} is preferably an (n_{L}+1)-valent linking group consisting of a combination of a group selected from an ether group or a thioether group, and an alkylene group. The above-described alkylene group may be linear, branched, or cyclic.

In addition, it is also preferable that the above-described (n_{L}+1)-valent hydrocarbon group does not have a silicon atom.

n_{L} preferably represents an integer of 3 to 8, more preferably represents an integer of 3 to 6, and still more preferably represents an integer of 3 to 5.

As Rh (substituent SI), a group represented by Formula (S2) is preferable.

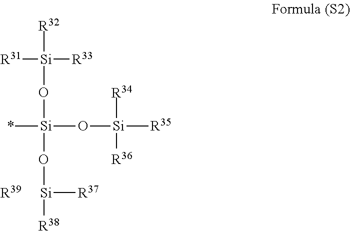

R³¹ to R³⁹ each independently represent an alkyl group, an alkenyl group, an aryl group, or an alkylene aryl group. R³¹ to R³⁹ are preferably an alkyl group (preferably an alkyl group having 1 to 3 carbon atoms), and more preferably a methyl group.

Examples of the repeating unit represented by Formula (3) include repeating units represented by Formulae B-8 to B-12. In Formula B-12, * represents a bonding position.

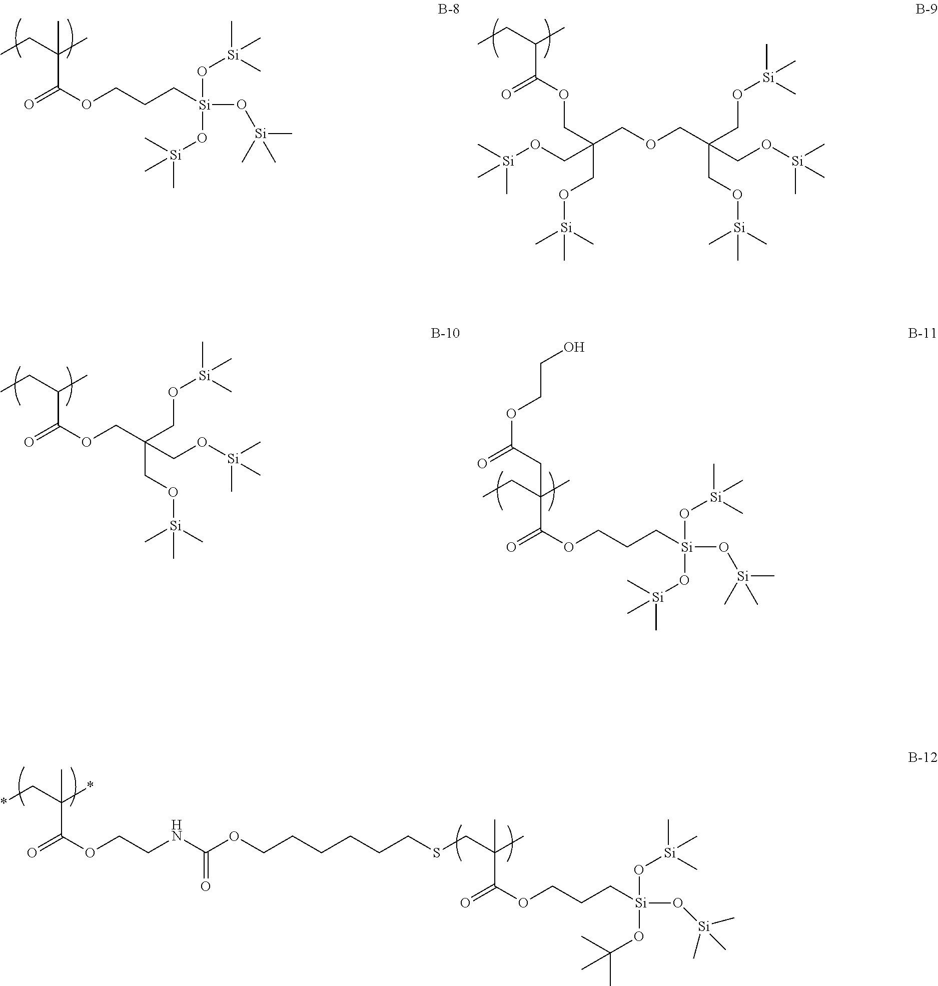

A content of the repeating unit represented by Formula (3) is not particularly limited, but for the reason that the liquid crystal alignment properties are further improved, it is preferably 1% to 15% by mass, and more preferably 2% to 10% by mass with respect to all repeating units of the photo-alignment polymer.

The photo-alignment polymer may further include a repeating unit C having a crosslinkable group, in addition to the above-described repeating units A and B and the above-described repeating unit represented by Formula (3).

The type of the crosslinkable group is not particularly limited, and examples thereof include a known cationically polymerizable group or a known radically polymerizable group.

Examples of the cationically polymerizable group include an epoxy group, an epoxycyclohexyl group, and an oxetanyl group.

Examples of the radically polymerizable group include an acryloyl group, a methacryloyl group, a vinyl group, a styryl group, and an allyl group.

From the reason that the liquid crystal alignment properties are further improved, the repeating unit C having a crosslinkable group is preferably a repeating unit represented by Formula (C).

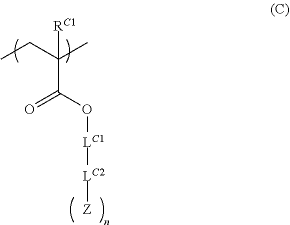

In Formula (C), R^{C1} represents a hydrogen atom or a substituent.

Here, examples of the substituent represented by one aspect of R^{C1} include the groups exemplified as the substituent represented by one aspect of R^{A1} in Formula (A) above.

R^{C1} is preferably a hydrogen atom or an alkyl group, and more preferably a hydrogen atom or a methyl group.

In Formula (C), L^{C1} represents a single bond or a divalent linking group.

Here, examples of the divalent linking group represented as one aspect of L^{C1} include the same group as those exemplified for the divalent linking group represented as one aspect of L^{A1} in Formula (A) described above. As L^{C1}, a linear alkylene group having 1 to 10 carbon atoms is preferable.

In Formula (C), L^{C2} represents an (n+1)-valent linking group.

Here, from the reason that the liquid crystal alignment properties are further improved, the (n+1)-valent linking group is an (n+1)-valent hydrocarbon group having 1 to 24 carbon atoms, which may have a substituent, and is preferably a hydrocarbon group in which a part of carbon atoms constituting the hydrocarbon group may be substituted with a heteroatom, and more preferably an aliphatic hydrocarbon group which may contain an oxygen atom or a nitrogen atom and has 1 to 10 carbon atoms.

The number of carbon atoms included in the (n+1)-valent linking group is not particularly limited, but from the reason that the liquid crystal alignment properties are further improved, the number thereof is preferably 1 to 24 and more preferably 1 to 10.

The (n+1)-valent linking group is preferably a divalent linking group. Examples of the divalent linking group as a suitable aspect include the same group as those exemplified for the divalent linking group represented as one aspect of L^{A1} in Formula (A) described above.

In Formula (C), Z represents a crosslinkable group.

Here, examples of the crosslinkable group include the cationically polymerizable group or radically polymerizable group described above.

In the present invention, from the reason that the liquid crystal alignment properties are further improved, the above-described crosslinkable group preferably represents a group represented by any of Formulae (C1) to (C4), and more preferably represents a group represented by any of Formulae (C1) to (C3).

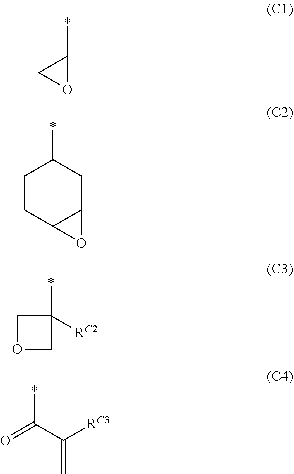

In Formulae (C1) to (C4), * represents a bonding position.

In addition, in Formula (C3), R^{C2} represents a hydrogen atom, a methyl group, or an ethyl group.

In addition, in Formula (C4), R^{C3} represents a hydrogen atom or a methyl group.

In Formula (C), n represents an integer of 1 or more. Among these, from the reason that the liquid crystal alignment properties are further improved, an integer of 1 to 5 is preferable, an integer of 1 to 3 is more preferable, and 1 or 2 is still more preferable.

Specific examples of the repeating unit C include repeating units represented by Formulae C-1 to C-10.

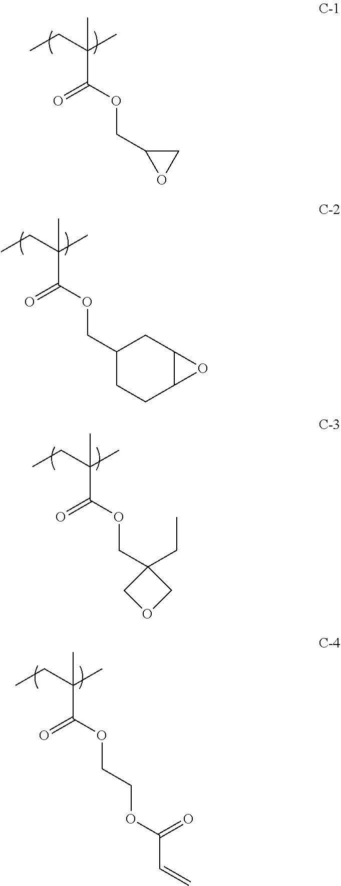

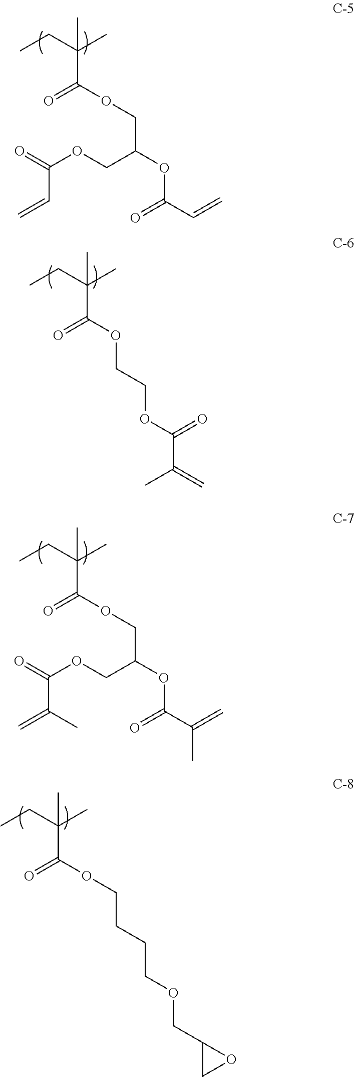

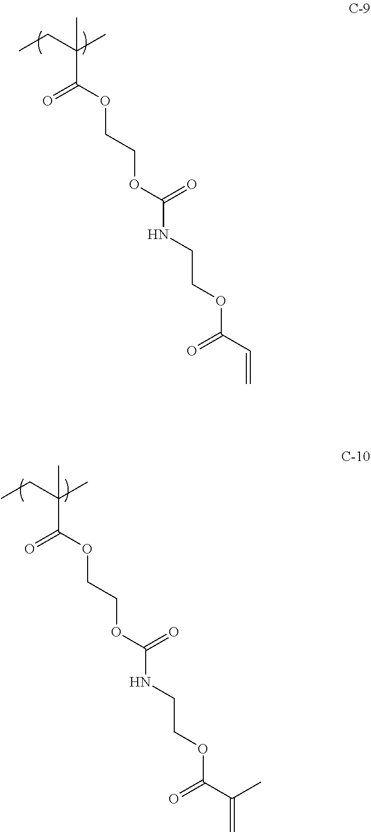

A content of the repeating unit C is not particularly limited, but for the reason that the liquid crystal alignment properties are further improved, it is preferably more than 60% by mass and less than 80% by mass, and more preferably 65% to 75% by mass with respect to all repeating units of the photo-alignment polymer.

The photo-alignment polymer may further include a repeating unit, in addition to the above-described repeating units A to C and the above-described repeating unit represented by Formula (3).

Examples of a monomer (radically polymerizable monomer) forming other repeating units include an acrylic acid ester compound, a methacrylic acid ester compound, a maleimide compound, an acrylamide compound, acrylonitrile, maleic acid anhydride, a styrene compound, and a vinyl compound.

A weight-average molecular weight (Mw) of the photo-alignment polymer is not particularly limited, but from the reason that the liquid crystal alignment properties are further improved, it is preferably 10,000 to 500,000, more preferably 10,000 to 300,000, and still more preferably 30,000 to 150,000.

Here, the weight-average molecular weight in the present invention is a value measured by gel permeation chromatography (GPC) under the following conditions.
Solvent (eluant): tetrahydrofuran (THF)
Device Name: TOSOH HLC-8320GPC
Column: Three items of TOSOH TSKgel Super HZM-H (4.6 mm×15 cm) are connected and used.
Column Temperature: 40° C.
Sample Concentration: 0.1% by mass
Flow Rate: 1.0 ml/min
Calibration curve: TSK standard polystyrene (manufactured by TOSOH Corporation), calibration curves of 7 samples with Mw of 2,800,000 to 1,050 (Mw/Mn=1.03 to 1.06) are used

As described above, the content of the photo-alignment polymer is 1% to 15% by mass, preferably 2% to 10% by mass, and more preferably 3% to 8% by mass with respect to the total solid content (total mass of solid contents) of the composition for forming a photo-alignment film.

### [Epoxy Compound]

The epoxy compound contained in the composition for forming a photo-alignment film is not particularly limited, and a known epoxy compound in the related art can be used.

Here, the epoxy compound is preferably a compound having an epoxy group which does not correspond to the above-described photo-alignment polymer, that is, a compound having an epoxy group and not having a photo-aligned group.

Examples of the epoxy compound include a bisphenol A-type epoxy compound, a bisphenol-F type epoxy compound, a brominated bisphenol A-type epoxy compound, a bisphenol S-type epoxy compound, a diphenyl ether-type epoxy compound, a hydroquinone-type epoxy compound, a naphthalene-type epoxy compound, a biphenyl-type epoxy compound, a fluorene-type epoxy compound, a phenol novolac-type epoxy compound, an orthocresol novolac-type epoxy compound, a trihydroxyphenylmethane-type epoxy compound, a trifunctional epoxy compound, a tetraphenylol ethane-type epoxy compound, a dicyclopentadiene phenol-type epoxy compound, a hydrogenated bisphenol A-type epoxy compound, a bisphenol A-contained polyol-type epoxy compound, a polypropylene glycol-type epoxy compound, a glycidyl ester-type epoxy compound, a glycidyl amine-type epoxy compound, a glycidyl ether-type epoxy compound, an alicyclic epoxy compound, and a heterocyclic epoxy compound.

Among these, an alicyclic epoxy compound is preferable.

Here, the alicyclic epoxy compound refers to a compound having at least one alicyclic epoxy group. In addition, the alicyclic epoxy group refers to a monovalent substituent having a condensed ring between an epoxy ring and a saturated hydrocarbon ring, and is preferably a monovalent substituent having a condensed ring between an epoxy ring and a cycloalkane ring. More preferred examples of the alicyclic epoxy compound include a compound having one or more structures in which an epoxy ring and a cyclohexane ring are fused in one molecule.

In the present invention, the epoxy compound is preferably a polymer having a repeating unit including an epoxy group (particularly, an alicyclic epoxy group) in a side chain.

From the reason that the photo-alignment polymer is likely to be unevenly distributed on the surface of the photo-alignment film, a molecular weight of the epoxy compound is preferably 1,000 or more.

In addition, from the viewpoint of ensuring solubility, the upper limit value of the molecular weight of the epoxy compound is preferably 100,000 or less.

In the present invention, the molecular weight of the epoxy compound is more preferably 2,000 to 70,000.

Examples of the epoxy compound having such a molecular weight include a polymer having a repeating unit in which Z in Formula (C) above is represented by the group represented by any one of Formulae (C1) and (C2), which is described as the repeating unit C of the photo-alignment polymer above.

A content of the epoxy compound is preferably 70% to 98% by mass and more preferably 85% to 95% by mass with respect to the total solid content of the composition for forming a photo-alignment film.

In the present invention, from the viewpoint of achieving both the liquid crystal alignment properties and the rub resistance, an element ratio of fluorine on one surface of the photo-alignment film (hereinafter, abbreviated as “specific surface” in the present paragraph and the subsequent paragraph) is preferably 0.5 to 3.0 atomic % and more preferably 1.5 to 3.0 atomic %. In particular, it is preferable that the elemental ratio of fluorine on a surface opposite to a substrate side used in the production of the photo-alignment film is in the above-described range.

In addition, the element ratio of fluorine on the specific surface is calculated by X-ray photoelectron spectroscopy (XPS).

Here, the element ratio of fluorine refers to a detection ratio of a fluorine element derived from the photo-alignment polymer to all elements detected from the specific surface.

The fluorine element derived from the photo-alignment polymer is quantified by a peak separation method of F1s spectrum. In the peak separation method, the measured F1s spectrum is separated into each component by using curve fitting by a least squares method. A peak area derived from the photo-alignment polymer among the separated peaks can be obtained by dividing the peak area by the total elemental ratio of the surface. As the component spectrum as a base for separation, F1s spectra obtained by measuring each of the photo-alignment polymer used in the production of the photo-alignment film and other components containing fluorine alone are used.

In the present invention, from the viewpoint of achieving both the liquid crystal alignment properties and the rub resistance, an element ratio of silicon on the specific surface is preferably 0.2 to 1.25 atomic %. In particular, it is preferable that the elemental ratio of silicon on a surface opposite to a substrate side used in the production of the photo-alignment film is in the above-described range.

The lower limit value of the element ratio of silicon on the specific surface is preferably 0.25 atomic % or more. Similarly, the upper limit value thereof is preferably 1.1 atomic % or less, and more preferably 1.0 atomic % or less.

In addition, the element ratio of silicon on the specific surface is calculated by X-ray photoelectron spectroscopy (XPS). Here, the element ratio of silicon refers to a detection ratio of a silicon element derived from the photo-alignment polymer to all elements detected from the specific surface.

From the reason for forming a stronger crosslinking to further improve the rub resistance, it is preferable that the photo-alignment film according to the embodiment of the present invention does not contain a liquid crystal compound.

A thickness of the photo-alignment film according to the embodiment of the present invention is not particularly limited and can be appropriately selected depending on the purpose, but is preferably 10 to 1,000 nm and more preferably 50 to 700 nm.

### [Thermal Acid Generator]

From the viewpoint of curing the above-described epoxy compound, the composition for forming a photo-alignment film preferably contains a thermal acid generator, that is, a catalyst which generates an acid by heating and cationically polymerizes an epoxy group by the action of the acid.

The thermal acid generator is not particularly limited as long as it can generate an acid by heat, and examples thereof include onium salts such as a sulfonium salt, a benzothiazolium salt, an ammonium salt, and a phosphonium salt.

Specific examples of the thermal acid generator include salts of a cation selected from benzyl (4-hydroxyphenyl)methylsulfonium, (4-acetoxyphenyl)dimethylsulfonium, (4-hydroxyphenyl)dimethylsulfonium, (2-methylbenzyl) (4-hydroxyphenyl)methylsulfonium, (1-naphthylmethyl) (4-hydroxyphenyl)methylsulfonium, or benzyl (4-acetoxyphenyl)methylsulfonium, and an anion selected from tris(pentafluoroethyl)trifluorophosphate, hexafluorophosphate, tetrafluoroborate, tetrakis(pentafluorophenyl)borate, hexafluoroantimonate, p-toluenesulfonate, dodecylbenzenesulfonate, trifluoromethanesulfonate, or perfluorobutanesulfonate.

### [Solvent]

From the viewpoint of workability, the composition for forming a photo-alignment film preferably contains a solvent.

Examples of the solvent include ketones (for example, acetone, 2-butanone, methyl isobutyl ketone, cyclopentanone, and cyclohexanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide).

The solvents may be used alone or in combination of two or more kinds thereof.

### [Method for Producing Photo-Alignment Film]

A method for producing the photo-alignment film according to the embodiment of the present invention is not particularly limited, and the photo-alignment film according to the embodiment of the present invention can be produced using the above-described composition for forming a photo-alignment film. For example, the photo-alignment film according to the embodiment of the present invention can be produced by a production method including a coating step of coating a surface of a support with the composition for forming a photo-alignment film to form a coating film, a heating step of heating and drying the coating film, and a light irradiating step of irradiating the coating film after drying with polarized light or non-polarized light in an oblique direction with respect to the surface of the coating film.

Hereinafter, each step in the production method will be described in detail.

### <Coating Step>

As the support used in the coating step, for example, a transparent support is suitably used. The term “transparent” in the present invention means that transmittance of visible light is 60% or more.

Examples of the transparent support include a glass substrate and a polymer film.

Specific examples of a polymer constituting the polymer film cellulose-based polymers; acrylic polymers having an acrylic acid ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

Among these, a cellulose-based polymer (hereinafter, also referred to as “cellulose acylate”) represented by triacetyl cellulose (TAC) can be preferably used.

In addition, the support may be a peelable temporary support after the photo-alignment film is formed.

A coating method in the coating step is not particularly limited and can be appropriately selected depending on the purposes, and examples of the method include spin coating, die coating, gravure coating, flexography, and ink jet printing.

### <Heating Step>

A temperature of the heating step is not particularly limited as long as the solvent contained in the coating film can be dried and removed and the epoxy compound can be cured, and is preferably 100° C. to 150° C.

In addition, a time of the heating step is not particularly limited as long as the solvent contained in the coating film can be dried and removed and the epoxy compound can be cured, but is preferably 30 seconds to 5 minutes.

### <Light Irradiating Step>

In the light irradiating step, the polarized light to be applied to the coating film after drying is not particularly limited, and examples thereof include linearly polarized light, circularly polarized light, and elliptically polarized light; and linearly polarized light is preferable.

In addition, the “oblique direction” in which irradiation with unpolarized light is performed is not particularly limited as long as it is a direction inclined at a polar angle θ (0°<θ<90°) with respect to a normal direction of the surface of the coating film. θ can be appropriately selected according to the purpose, and is preferably 20° to 80°.

A wavelength of the polarized light or the unpolarized light is not particularly limited as long as the light is light to which the photo-aligned group is exposed. Examples thereof include ultraviolet rays, near-ultraviolet rays, and visible rays, and near-ultraviolet rays of 250 to 450 nm are preferable.

In addition, examples of a light source for irradiating the coating film after drying with polarized light or non-polarized light include a xenon lamp, a high-pressure mercury lamp, an ultra-high pressure mercury lamp, a light emitting diode (LED) lamp, and a metal halide lamp. By using an interference filter, a color filter, or the like with respect to ultraviolet rays or visible rays obtained from the light source, the wavelength range of the irradiation can be restricted. In addition, linearly polarized light can be obtained by using a polarization filter or a polarization prism with respect to the light from the light source.

An integrated quantity of the polarized light or the unpolarized light is not particularly limited, and is preferably 1 to 300 mJ/cm² and more preferably 5 to 100 mJ/cm².

An illuminance of the polarized light or the unpolarized light is not particularly limited, and is preferably 0.1 to 300 mW/cm² and more preferably 1 to 100 mW/cm².

### [Optical Film]

The optical film according to the embodiment of the present invention is an optical film including the above-described photo-alignment film according to the embodiment of the present invention and a liquid crystal cured layer.

Here, the liquid crystal cured layer is a layer obtained by fixing an alignment state of a liquid crystal composition containing a liquid crystal compound, and in the present invention, the liquid crystal cured layer is preferably a layer obtained by fixing an alignment state of a liquid crystal composition containing a disk-like liquid crystal compound.

The liquid crystal compound can be classified into a rod-like type and a disk-like type according to the shape thereof. Furthermore, each type includes a low-molecular-weight type and a high-molecular-weight type. The term “high-molecular-weight” generally refers to a compound having a degree of polymerization of 100 or more (Polymer Physics-Phase Transition Dynamics, written by Masao Doi, p. 2, published by Iwanami Shoten, 1992). In the present invention, any liquid crystal compound can be used, and a rod-like liquid crystal compound or a disk-like liquid crystal compound (discotic liquid crystal compound) is preferable.

In addition, from the viewpoint of fixing the alignment state of the liquid crystal composition, the liquid crystal compound preferably has a polymerizable group. Examples of the polymerizable group include an acryloyl group, a methacryloyl group, an epoxy group, and a vinyl group.

By polymerizing such a liquid crystal compound, the alignment of the liquid crystal compound can be fixed. After immobilizing the liquid crystal compound by polymerization, it is no longer necessary to exhibit liquid crystallinity.

As the rod-like liquid crystal compound, for example, those described in Claim 1 of JP1999-513019A (JP-H11-513019A) or paragraphs [0026] to [0098] of JP2005-289980A are preferable; and as the disk-like liquid crystal compound, those described in paragraphs [0020] to [0067] of JP2007-108732A or paragraphs [0013] to [0108] of JP2010-244038A are preferable.

A liquid crystal compound having reverse wavelength dispersibility can be used as the above-described polymerizable liquid crystal compound.

Here, in the present specification, the liquid crystal compound having “reverse wavelength dispersibility” refers to the fact that in the measurement of an in-plane retardation (Re) value at a specific wavelength (visible light range) of a retardation film produced using the liquid crystal compound, as the measurement wavelength increases, the Re value is the same or increased.

The liquid crystal compound having reverse wavelength dispersibility is not particularly limited as long as a film having reverse wavelength dispersibility can be formed as described above, and examples thereof include compounds represented by Formula (I) described in JP2008-297210A (particularly, compounds described in paragraphs [0034] to [0039]), compounds represented by Formula (1) described in JP2010-084032A (particularly, compounds described in paragraphs [0067] to [0073]), and compounds represented by Formula (1) described in JP2016-081035A (particularly, compounds described in paragraphs [0043] to [0055]).

Examples thereof further include compounds described in paragraphs [0027] to [0100] of JP2011-006360A, paragraphs [0028] to [0125] of JP2011-006361A, paragraphs [0034] to [0298] of JP2012-207765A, paragraphs [0016] to [0345] of JP2012-077055A, paragraphs [0017] to [0072] of WO2012/141245A, paragraphs [0021] to [0088] of WO2012/147904A, and paragraphs [0028] to [0115] of WO2014/147904A.

The liquid crystal cured layer can be cured by a known method using the liquid crystal composition containing the liquid crystal compound. The liquid crystal composition may contain known materials such as a polymerization initiator, a polyfunctional monomer, a photoacid generator, an alignment control agent (a vertical alignment agent or a horizontal alignment agent), a surfactant, an adhesion improver, a plasticizer, and a solvent, in addition to the above-described liquid crystal compound.

The alignment state of the liquid crystal compound in the liquid crystal cured layer may be any of a horizontal alignment state, a homeotropic alignment, a tilt alignment state, or a twisted alignment state; and it is preferable that the disk-like liquid crystal compound is immobilized in a homeotropic alignment state.

In the present specification, the “homeotropic alignment” refers to that a disc plane of the disk-like liquid crystal compound and a coating film surface (main surface of the liquid crystal cured layer) are perpendicular to each other. The term “perpendicular” does not require that the disc plane of the disk-like liquid crystal compound and the coating film surface are strictly perpendicular to each other, but means an alignment in which a tilt angle between the disc plane of the disk-like liquid crystal compound and the coating film surface is 70° or more. The tilt angle is preferably 85° to 90°, more preferably 87° to 90°, still more preferably 88° to 90°, and most preferably 89° to 90°.

In the present invention, from the reason that the effect of the present invention, particularly the effect of the rub resistance is manifested, an angle formed between a slow axis of the liquid crystal cured layer and a longitudinal direction of the optical film is preferably 50° to 90°. It is preferable that the above-described liquid crystal cured layer is formed of a disk-like liquid crystal compound.

### [Circularly Polarizing Plate]

The optical film according to the embodiment of the present invention may be used as a circularly polarizing plate in combination with a polarizer. The circularly polarizing plate is an optical element which converts unpolarized light into circularly polarized light.

The polarizer may be a member having a function of converting natural light into specific linearly polarized light, and examples thereof include an absorption type polarizer.

The type of the polarizer is not particularly limited, and a commonly used polarizer can be used. Examples thereof include an iodine-based polarizer, a dye-based polarizer using a dichroic substance, and a polyene-based polarizer. The iodine-based polarizer and the dye-based polarizer are generally produced by adsorbing iodine or a dichroic dye on a polyvinyl alcohol, followed by stretching.

A protective film may be disposed on one side or both sides of the polarizer.

An arrangement relationship between an absorption axis of the polarizer and the optical film is not particularly limited, and an optimum arrangement is selected according to the type of the liquid crystal cured layer included in the optical film.

The circularly polarizing plate may include a member other than the optical film according to the embodiment of the present invention and the polarizer. The circularly polarizing plate may include an adhesion layer between the optical film according to the embodiment of the present invention and the polarizer.

Examples of the adhesion layer include known pressure sensitive adhesive layers and adhesive layers.

A method for manufacturing the circularly polarizing plate is not particularly limited, and a known method can be mentioned.

For example, a method of bonding the polarizer and the optical film through the adhesion layer can be mentioned.

In the circularly polarizing plate, the photo-alignment film may be peeled off from the optical film after bonding the optical film to the polarizer.

Another example of the method for manufacturing a circularly polarizing plate includes a method for manufacturing a circularly polarizing plate, including, in the following order, a step 1 of producing an optical film by applying a liquid crystal composition containing a liquid crystal compound on the photo-alignment film according to the embodiment of the present invention and curing the liquid crystal composition to form a liquid crystal cured layer, a step 2 of bonding the optical film to a polarizer, and a step 3 of peeling off the photo-alignment film from the optical film.

### [Image Display Apparatus]

The image display apparatus according to the embodiment of the present invention is an image display apparatus including the above-described photo-alignment film according to the embodiment of the present invention.

The display element which is used in the image display apparatus according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable, and a liquid crystal cell is more preferable. That is, the image display apparatus according to the embodiment of the present invention is preferably a liquid crystal display device using a liquid crystal cell as a display element or an organic EL display device using an organic EL display panel as a display element.

### EXAMPLES

Hereinafter, the present invention will be described in more detail with reference to examples. The materials, amounts used, proportions, treatment details, treatment procedure, and the like shown in the following Examples can be appropriately changed without departing from the spirit and scope of the present invention. Therefore, the scope of the present invention should not be construed as being limited to Examples.

### Example 1

### [Production of Cellulose Acylate Film 1 (Substrate)]

### <Production of Core Layer Cellulose Acylate Dope>

The following composition was put into a mixing tank and stirred to dissolve each component, thereby preparing a cellulose acetate solution used as a core layer cellulose acylate dope.

Core layer cellulose acylate dope

| | | |
|---|---|---|
| Cellulose acetate having acetyl substitution degree of 2.88 | 100 | parts by mass |
| Polyester compound B described in Examples of JP2015-227955A | 8 | parts by mass |
| The following compound G | 4 | parts by mass |
| Methylene chloride (first solvent) | 430 | parts by mass |
| Methanol (second solvent) | 64 | parts by mass |

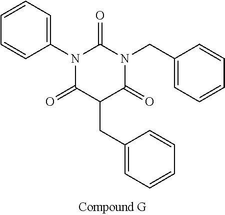 [SMILES: O=C1C(Cc2ccccc2)C(=O)N(c2ccccc2)C(=O)N1Cc1ccccc1]

### <Production of Outer Layer Cellulose Acylate Dope>

10 parts by mass of the following matting agent solution was added to 90 parts by mass of the above-described core layer cellulose acylate dope to prepare a cellulose acetate solution used as an outer layer cellulose acylate dope.

Matting agent solution

| | | |
|---|---|---|
| Silica particles having an average particle diameter | 2 | parts by mass |
| of 20 nm (AEROSIL R972, manufactured by | | |
| Nippon Aerosil Co., Ltd.) | | |
| Methylene chloride (first solvent) | 76 | parts by mass |
| Methanol (second solvent) | 11 | parts by mass |
| Core layer cellulose acylate dope described above | 1 | part by mass |

The core layer cellulose acylate dope and the outer layer cellulose acylate dope were filtered through filter paper having an average hole diameter of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

The film was peeled off in a state in which the solvent content was approximately 20% by mass, both ends of the film in the width direction were fixed by tenter clips, and the film was dried while being stretched at a stretching ratio of 1.1 times in the lateral direction. Thereafter, the film was transported between rolls in a heating treatment device, and further dried to produce an optical film having a thickness of 40 μm, which was regarded as a cellulose acylate film 1.

The obtained cellulose acylate film 1 had an in-plane retardation of 0 nm at a wavelength of 550 nm. The obtained cellulose acylate film 1 was used as a substrate.

### [Formation of Photo-Alignment Film PA-1]

### <Preparation of Composition 1 for Forming Photo-Alignment Film>

A composition 1 for forming a photo-alignment film, having the following formulation, was prepared.

Composition 1 for forming photo-alignment film

| | | |
|---|---|---|
| Photo-alignment polymer P-1 shown below | 1.5 | parts by mass |
| Epoxy compound E-1 shown below | 98.5 | parts by mass |
| Thermal acid generator B shown below | 6.0 | parts by mass |
| Diisopropylethylamine | 0.6 | parts by mass |
| Butyl acetate | 594.0 | parts by mass |
| Methyl ethyl ketone | 306.0 | parts by mass |

Photo-alignment polymer P-1 [number attached to each repeating unit: mass ratio of each unit to all repeating units; weight-average molecular weight: 60,000]

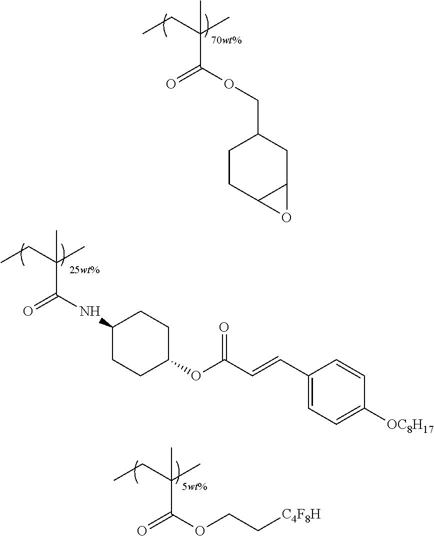

Epoxy compound E-1 [polyorganosilsesquioxane compound (A) described in Examples of WO2020/110966A; weight-average molecular weight: 3,900]

### Thermal Acid Generator B

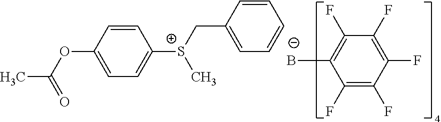

An air surface of the cellulose acylate film 1 was continuously coated with the composition 1 for forming a photo-alignment film using a geeser coating machine to form a coating film.

Next, the coating film was dried in a heating zone at 130° C. for 1 minute to remove the solvent, thereby forming a cured film having a thickness of 0.5 μm.

Next, the cured film was irradiated with ultraviolet rays (10 mJ/cm², light source: ultra-high pressure mercury lamp, measurement wavelength: 313 nm) through a wire grid polarizer to form a photo-alignment film PA-1. In this case, a transmission axis of the wire grid polarizer was set to an angle of 14° with respect to a longitudinal direction of the film.

### [Formation of Liquid Crystal Cured Layer LC-1]

A coating liquid (1a) for forming a liquid crystal cured layer, containing a disk-like liquid crystal compound having the following formulation, was applied onto the photo-alignment film PA-1 produced above using a geeser coating machine to form a composition layer.

Thereafter, the obtained composition layer was heated with hot air for 2 minutes such that the temperature of the film was 90° C., for drying the solvent and aligning and aging the disk-like liquid crystal compound.

Next, the obtained composition layer was irradiated with UV (100 mJ/cm², light source: metal halide, measurement wavelength: 365 nm) under N₂ purging at 80° C. to fix the alignment of the liquid crystal compound and form a liquid crystal cured layer LC-1, thereby producing an optical film.

A thickness of the liquid crystal cured layer LC-1 was 1.4 μm. In addition, a retardation at a wavelength of 550 nm was 168 nm. It was confirmed that an average tilt angle of a disc plane of the disk-like liquid crystal compound with respect to the film surface was 90°, and the disk-like liquid crystal compound was aligned perpendicular to the film surface. In addition, an angle between a slow axis of the liquid crystal cured layer LC-1 and a longitudinal direction of the film was 76°.

Coating liquid (1a) for forming liquid crystal cured layer

| | | |
|---|---|---|
| Disk-like liquid crystal compound 1 shown below | 80 | parts by mass |
| Disk-like liquid crystal compound 2 shown below | 20 | parts by mass |
| Alignment film interface alignment agent 1 shown below | 2.0 | parts by mass |
| Fluorine-containing compound A shown below | 0.10 | parts by mass |
| Fluorine-containing compound B shown below | 0.06 | parts by mass |
| Fluorine-containing compound C shown below | 0.21 | parts by mass |
| Ethylene oxide-modified trimethylolpropane triacrylate (V # 360, manufactured by Osaka | 5 | parts by mass |
| Organic Chemical Industry Ltd.) | | |
| Photopolymerization initiator (Api307, (1-(biphenyl-4-yl)-2-methyl-2-morpholinopropan-1- | 4 | parts by mass |
| one, manufactured by Shenzhen UV-ChemTech Co., Ltd.) | | |
| Methyl ethyl ketone | 250 | parts by mass |

Disk-like liquid crystal compound 1 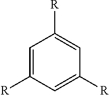 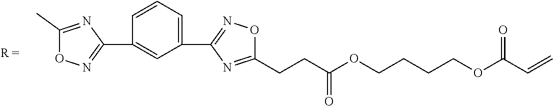 [SMILES: C=CC(=O)OCCCCOC(=O)CCc1nc(-c2cccc(-c3noc(C)n3)c2)no1]
Disk-like liquid crystal compound 2 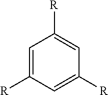 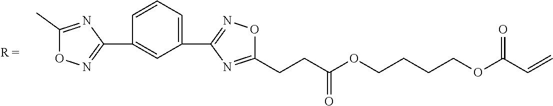 [SMILES: C=CC(=O)OCCCCOC(=O)CCc1nc(-c2cccc(-c3noc(C)n3)c2)no1]
Alignment film interface alignment agent 1

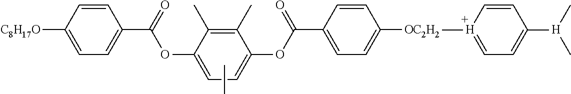

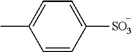

Fluorine-containing compound A [in the following formula, a and b represents a content (% by mass) of each repeating unit with respect to all repeating units, and a was 90% by mass and b was 10% by mass; in addition, a weight-average molecular weight was 15,000]

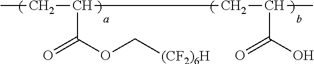

Fluorine-containing compound B [numerical value in each repeating unit represents a content (% by mass) with respect to all repeating units; in addition, a weight-average molecular weight was 12,500]

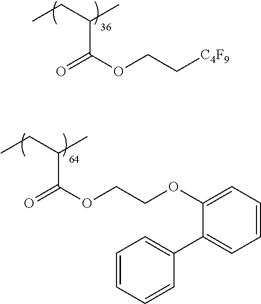

Fluorine-containing compound C [numerical value in each repeating unit represents a content (% by mass) with respect to all repeating units; in addition, a weight-average molecular weight was 12,500]

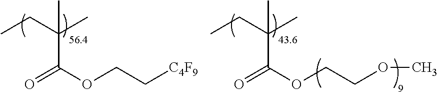

### Examples 2 to 7 and Comparative Examples 1 to 4

An optical film was produced by the same method as in Example 1, except that the content or type of the photo-alignment polymer and the type or presence or absence of the epoxy compound were changed as shown in Table 1 below.

In Examples 2 to 7 and Comparative Examples 1 to 4, the addition amounts of the photo-alignment polymer and the epoxy compound were adjusted so that the total amount of the photo-alignment polymer and the epoxy compound was set to 100 parts by mass and the solid content ratio (% by mass) of the photo-alignment polymer in Table 1 was as follows. For example, the composition 2 for forming a photo-alignment film of Example 2 had the same formulation as the composition 1 for forming a photo-alignment film of Example 1, except that the photo-alignment polymer P-1 was changed to 6.5 parts by mass and the epoxy compound E-1 was changed to 93.5 parts by mass.

### [Evaluation]

### [Evaluation of Liquid Crystal Alignment Properties]

The produced optical film was sandwiched between two polarizing plates of crossed nicols, placed so as to be deviated from the extinction position by 5°, and observed on a light box; and the presence or absence of unevenness which could be visually recognized was determined.

In addition, in a case where there was no unevenness on the light box, observation was performed in a state in which the extinction position was shifted by 5° using a polarization microscope. The evaluation was performed according to the following standard. The results are shown in Table 1 below.
A: unevenness was not visible with the light box, and there was no disorder in the liquid crystal director.
B: unevenness was not visible with the light box, and the disorder of the liquid crystal director was very small.
C: unevenness was not visible with the light box, and the disorder of the liquid crystal director was observed as a whole.
D: unevenness was visible with the light box.

### [Rub Resistance]

The surface of the photo-alignment film produced in each example and subjected to polarization exposure was scratched in the longitudinal direction of the film, with a continuous weighted scratch resistance strength tester (manufactured by Shinto Scientific Co., Ltd.) at a load of 0.5 g. Here, a conical diamond indenter (conical angle: 90°, curvature radius of tip: 150 μm) was used as the scratch indenter, the load condition was 0.5 g, and the speed was 300 mm/min.

After the scratching, the coating liquid for forming a liquid crystal cured layer, used in each example, was immediately applied in the longitudinal direction of the film, and a liquid crystal cured layer was formed by the same method as in each example, thereby producing an optical film.

The produced optical film was sandwiched between two polarizing plates of crossed nicols, placed so as to be deviated from the extinction position by 5°, and observed on a light box. The scratched portion was evaluated according to the following standard. The results are shown in Table 1 below.
A: unevenness was not visible with the light box.
B: unevenness was visible in a discontinuous manner in the direction in which the film was scratched by the light box.
C: continuous unevenness was visible in the direction in which film was scratched by the light box.

### [Element Ratio of Fluorine]

For the surface of the photo-alignment film produced in each example and subjected to polarization exposure, an element ratio of fluorine derived from the photo-alignment polymer was measured by the above-described method. The results are shown in Table 1 below.

TABLE 1

| | Photo-alignment polymer | | | Evaluation | | |
|---|---|---|---|---|---|---|
| | | Amount with | | Liquid | | |
| | | respect to | | crystal | | Element ratio |
| | | total solid | Epoxy | alignment | Rub | of fluorine |
| | Type | content | compound | properties | resistance | (atomic %) |
| Example 1 | P-1 | 1.4 | E-1 | A | B | 0.6 |
| Example 2 | P-1 | 6.1 | E-1 | A | B | 2.5 |
| Example 3 | P-1 | 9.4 | E-1 | A | B | 2.8 |
| Example 4 | P-2 | 6.1 | E-1 | A | A | 2.5 |
| Example 5 | P-2 | 6.1 | E-2 | A | A | 2.6 |
| Example 6 | P-3 | 6.1 | E-1 | B | B | 2.8 |
| Example 7 | P-4 | 6.1 | E-2 | B | B | 2.6 |
| Comparative | P-1 | 94 | | A | C | 3.3 |
| Example 1 | | | | | | |
| Comparative | P-1 | 0.5 | E-1 | D | C | 0.2 |
| Example 2 | | | | | | |
| Comparative | P-1 | 19 | E-1 | A | C | 3.1 |
| Example 3 | | | | | | |
| Comparative | P-3 | 19 | E-1 | D | C | 3.7 |
| Example 4 | | | | | | |

Structures of the photo-alignment polymer and the epoxy compound in Table 1 are shown below.

Photo-alignment polymer P-1 [number attached to each repeating unit: mass ratio of each unit to all repeating units; weight-average molecular weight: 60,000]

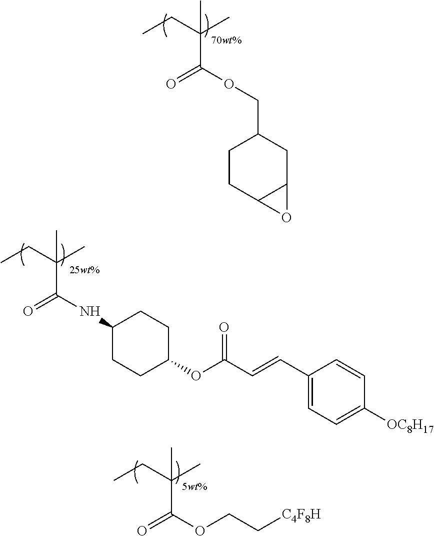

Photo-alignment polymer P-2 [number attached to each repeating unit: mass ratio of each unit to all repeating units; weight-average molecular weight: 60,000]

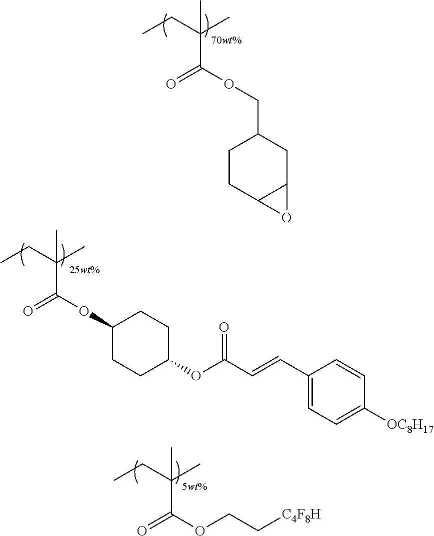

Photo-alignment polymer P-3 [number attached to each repeating unit: mass ratio of each unit to all repeating units; weight-average molecular weight: 60,000]

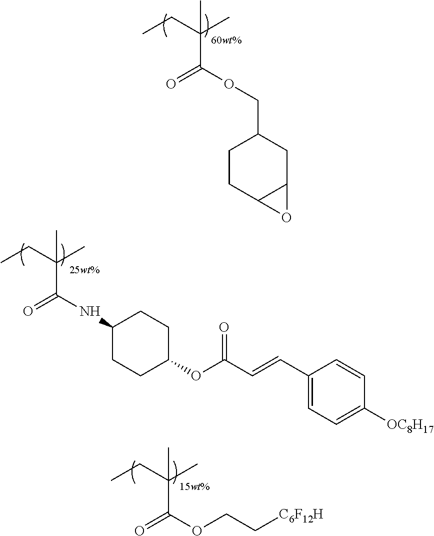

Photo-alignment polymer P-4 [number attached to each repeating unit: mass ratio of each unit to all repeating units; weight-average molecular weight: 60,000]

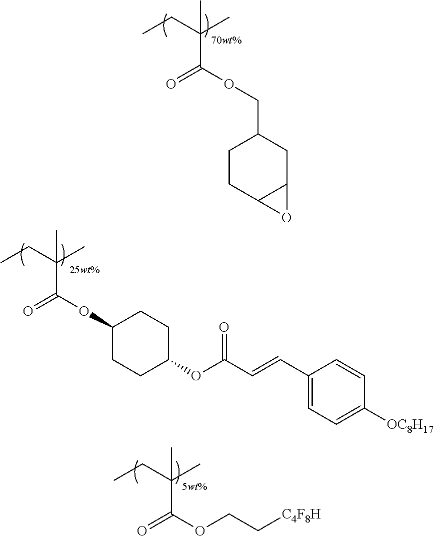

Epoxy compound E-1 [polyorganosilsesquioxane compound (A) described in Examples of WO2020/110966A; weight-average molecular weight: 3,900]

Epoxy compound E-2 [weight-average molecular weight: 50,000]

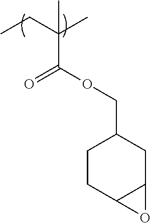

From the results shown in Table 1 above, it was found that, in a case where the content of the photo-alignment polymer was outside the range of 1% to 15% by mass with respect to the mass of the photo-alignment film, the rub resistance was deteriorated (Comparative Examples 1 to 4).

On the other hand, it was found that, in a case where the content of the photo-alignment polymer was in the range of 1% to 15% by mass with respect to the mass of the photo-alignment film, the liquid crystal alignment properties and the rub resistance were improved (Examples 1 to 6).

### Examples 8 and 9 and Comparative Example 5

An optical film was produced by the same method as in Example 1, except that the content or type of the photo-alignment polymer and the type of the epoxy compound were changed as shown in Table 2 below.

### [Evaluation]

The liquid crystal alignment properties and the rub resistance of the optical films produced in Examples 8 and 9 and Comparative Example 5 were evaluated by the same method as in Example 1.

In addition, for the surface of the photo-alignment films produced in Examples 8 and 9 and Comparative Example 5 and subjected to polarization exposure, an element ratio of silicon derived from the photo-alignment polymer was measured by the above-described method.

The results are shown in Table 2 below.

TABLE 2

| | Photo-alignment polymer | | | Evaluation | | |
|---|---|---|---|---|---|---|
| | | Amount with | | Liquid | | |
| | | respect to | | crystal | | Element ratio |
| | | total solid | Epoxy | alignment | Rub | of fluorine |
| | Type | content | compound | properties | resistance | (atomic %) |
| Example 8 | P-5 | 6.1 | E-2 | B | A | 0.2 |
| Example 9 | P-6 | 6.1 | E-2 | A | A | 1.0 |
| Comparative | P-6 | 93.8 | E-2 | D | B | 1.5 |
| Example 5 | | | | | | |

Structures of the photo-alignment polymers in Table 2 are shown below.

Photo-alignment polymer P-5 [number attached to each repeating unit: mass ratio of each unit to all repeating units; weight-average molecular weight: 60,000]

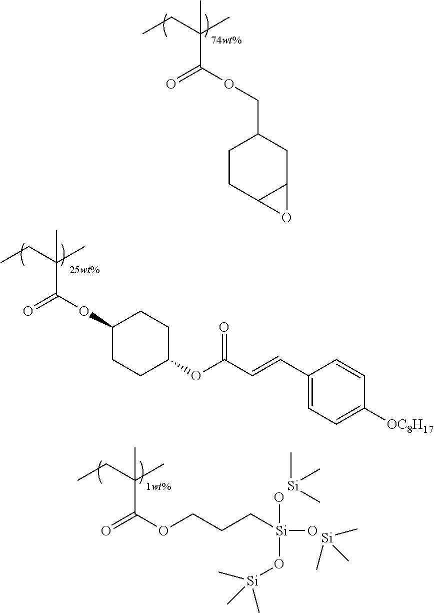

Photo-alignment polymer P-6 [number attached to each repeating unit: mass ratio of each unit to all repeating units; weight-average molecular weight: 60,000]

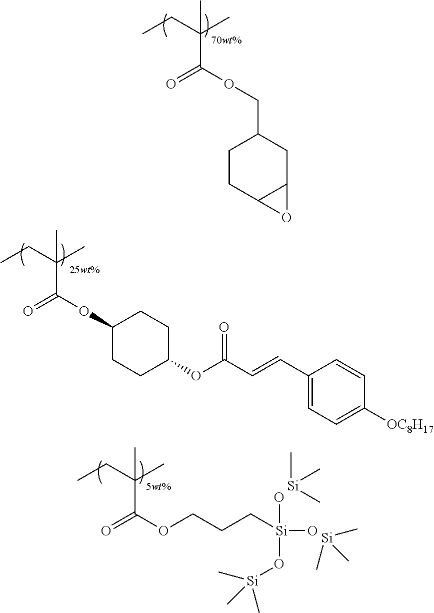

From the results shown in Table 2 above, it was found that, even in a case where the photo-alignment film contained a silicon atom, when the content of the photo-alignment polymer was in the range of 1% to 15% by mass with respect to the mass of the photo-alignment film, the liquid crystal alignment properties and the rub resistance were improved (Examples 8 and 9).

What is claimed is:

1. A photo-alignment film obtained by curing a composition which contains a photo-alignment polymer having a photo-aligned group and an epoxy compound,
wherein the photo-alignment film contains a fluorine atom or a silicon atom, and
a content of the photo-alignment polymer is 1% to 15% by mass with respect to a total solid content of the composition.

2. The photo-alignment film according to claim 1,
wherein an element ratio of fluorine on one surface of the photo-alignment film is 0.5 to 3.0 atomic %.

3. The photo-alignment film according to claim 1,
wherein an element ratio of silicon on one surface of the photo-alignment film is 0.2 to 1.25 atomic %.

4. The photo-alignment film according to claim 1,
wherein the photo-alignment polymer contains a fluorine atom.

5. The photo-alignment film according to claim 1,
wherein the photo-alignment polymer contains a silicon atom.

6. The photo-alignment film according to claim 1,
wherein the photo-alignment polymer has a repeating unit represented by Formula (A), 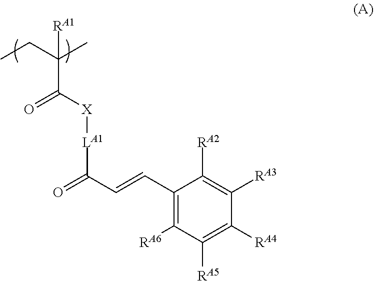
in Formula (A), R^{A1} represents a hydrogen atom or a substituent,
L^{A1} represents a single bond or a divalent linking group,
R^{A2}, R^{A3}, R^{A4}, R^{A5}, and R^{A6} each independently represent a hydrogen atom or a substituent, and two adjacent groups of R^{A2}, R^{A3}, R^{A4}, R^{A5}, and R^{A6} may be bonded to each other to form a ring.

7. The photo-alignment film according to claim 1,
wherein the photo-alignment film contains no liquid crystal compound.

8. An optical film comprising:
the photo-alignment film according to claim 1; and
a liquid crystal cured layer.

9. The optical film according to claim 8,
wherein an angle between a slow axis of the liquid crystal cured layer and a longitudinal direction of the optical film is 50° to 90°.

10. The optical film according to claim 8,
wherein the liquid crystal cured layer is a layer obtained by fixing an alignment state of a liquid crystal composition containing a disk-like liquid crystal compound.

11. A circularly polarizing plate comprising:
the optical film according to claim 8; and
a polarizer.

12. An image display apparatus comprising:
the photo-alignment film according to claim 1.

13. A method for manufacturing a circularly polarizing plate, comprising, in the following order:
a step 1 of producing an optical film by applying a liquid crystal composition containing a liquid crystal compound on the photo-alignment film according to claim 1 and curing the liquid crystal composition to form a liquid crystal cured layer;
a step 2 of bonding the optical film to a polarizer; and
a step 3 of peeling off the photo-alignment film from the optical film.
